(19) United States
(12) Patent Application Publication
(10) Pub. No.: US 2007/0138585 A1
(43) Pub. Date: Jun. 21, 2007

(54) Image sensor package

(76) Inventors: Chung Hsien Hsin, Hsinchu Hsien (TW); Chen pin Peng, Hsinchu Hsien (TW); Mon Nan Ho, Hsinchu Hsien (TW)

Correspondence Address: PRO-TECHTOR INTERNATIONAL SERVICES, 20775 NORADA CT., SARATOGA, CA, 95070, US

(21) Appl. No.: 11/305,654

(22) Filed: Dec. 16, 2005

(51) Int. Cl. H01L 31/0203

(52) U.S. Cl. 257/433; 257/432; 257/434

(57) ABSTRACT

An image sensor package includes a substrate having an upper surface, which is formed with a chip region and first electrodes located on the periphery of the chip region, and a lower surface. A chip is mounted on the chip region of the upper surface of the substrate. A frame layer is arranged on the upper surface of the substrate to surround the chip. Four posts are arranged on the upper surface of the substrate and are located on the angle the frame layer. A plurality of wires are electrically connected the bonding pads of the chip to the first electrodes of the substrate. A transparent layer is mounted on the four posts to cover the chip.

### BACKGROUND OF THE INVENTION

1. Field of the Invention

The invention relates an image sensor package, and particular to a structure for packaging image sensor, the size of the package may be decreased.

2. Description of the Related Art

Referring to FIG. 1, it is an image sensor structure includes a substrate 10, frame layer 18, a chip 26, a plurality of wires 28, transparent layer 34, a lens holder 35 and a lens barrel 46.

The substrate 10 has an first surface 12 on which plurality of first electrodes 15 are formed, and a second surface 14 on which plurality of second electrodes 16 are formed, the first electrodes 15 are corresponding to electrically connect to the second electrodes 16.

The frame layer 18 has a upper surface 20 and a lower surface 22, the lower surface 22 of the frame layer 18 is adhered on the first surface 22 of the substrate 10 to form a cavity 24.

The chip 26 is arranged on the first surface 12 of the substrate 10, and is located within the cavity 24, and is formed with bonding pads 27.

The wire 28 has a first end 30 and a second end 32, the first end 30 is electrically connected the bonding pad 27 of the chip 26, the second end 30 is electrically connected the first electrodes 15 of the substrate 10.

The transparent layer 34 is adhered on the upper surface 20 of the frame layer 18.

### SUMMARY OF THE INVENTION

An objective of the invention is to provide an image sensor package, and capable of decreasing the size of the module.

To achieve the above-mentioned object, the invention includes a substrate having an upper surface, which is formed with a chip region and first electrodes located on the periphery of the chip region, and a lower surface. A chip is mounted on the chip region of the upper surface of the substrate. A frame layer is arranged on the upper surface of the substrate to surround the chip. Four posts are arranged on the upper surface of the substrate and are located on the angle the frame layer. A plurality of wires are electrically connected the bonding pads of the chip to the first electrodes of the substrate. And a transparent layer is mounted on the four posts to cover the chip.

### BRIEF DESCRIPTION OF THE DRAWINGS

FIG. 1 is a schematic illustration showing a conventional image sensor package.

FIG. 2 is a cross-sectional schematic illustration showing an image sensor package of the present invention.

FIG. 3 is a top-view schematic illustration showing an image sensor package of the present invention.

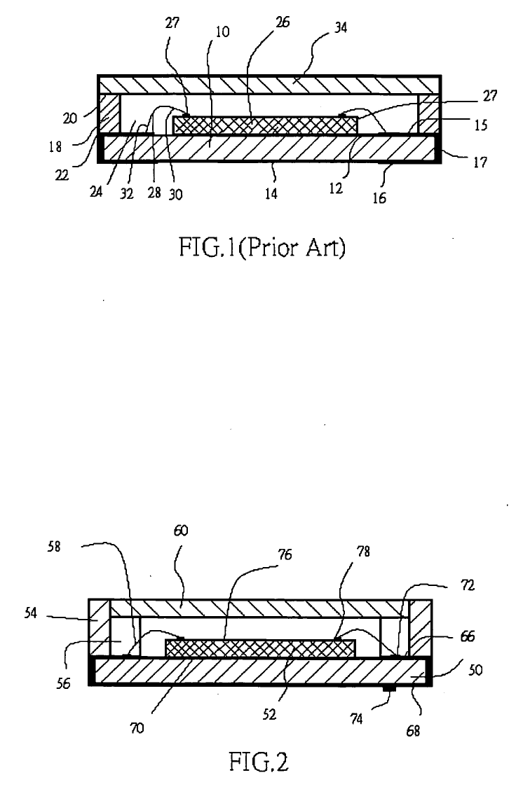

### DETAILED DESCRIPTION OF THE INVENTION

Please refer to FIG. 2, an image sensor package includes a substrate 50, a chip 52, a frame layer 54, four posts 56, wires 58, a transparent layer 60, a lens holder 62, and a lens barrel 64.

The substrate 50 has an upper surface 66, which is formed with a chip region 70 and first electrodes 72 are located on the periphery of the chip region 70, and a lower surface 68, which is formed with second electrodes 74 corresponding to electrically connect to the first electrodes 72.

The chip 52 is mounted on the chip region 70 of the upper surface 66 of the substrate 50, the chip has a sensor region 76 and a plurality of bonding pads 78 located at the side of the sensor region 70 of the chip 52.

The frame layer 54 is arranged on the upper surface 66 of the substrate 50 to surround the chip region 70 and the first electrodes 72.

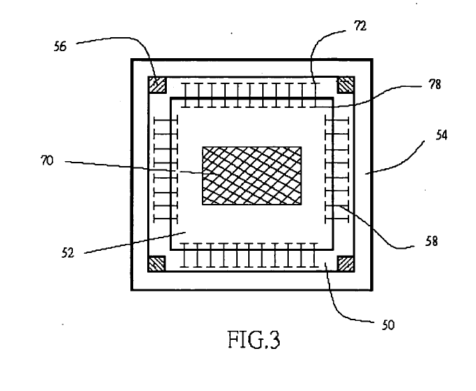

Please refer to FIG. 3, the four posts 56 are arranged on the upper surface 66 of the substrate 50 and are located on the angle the frame layer 54.

The plurality of wires 58 are electrically connected the bonding pads 78 of the chip 52 to the first electrodes 72 of the substrate 50. And

The transparent layer 60 is mounted on the four posts 56 to cover the chip 52.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

1. An image sensor package, the package comprising;
a substrate having an upper surface, having a central chip region and a plurality of first electrodes located on the periphery of the chip region, and a lower surface, with a plurality of second electrodes having electrically connections to the first electrodes;
a chip mounted on the chip region of the upper surface of the substrate, the chip having a sensor region and a plurality of bonding pads located at a peripheral side of the sensor region of the chip;
a plurality of wires electrically connecting the bonding pads of the chip to respective first electrodes of the substrate;
a frame layer wall having a rectangular plan with four interior corners, arranged near the periphery of the upper surface of the substrate to immediately surround the chip region and the first electrodes;
four posts of a uniform height arranged on the upper surface of the substrate, with one post located at each of the interior corners of the frame layer wall,
a transparent layer mounted on the four posts to cover the chip;
wherein the height of the four posts are lower than the frame layer wall, creating a recess whereby the transparent layer may rest interior of the frame layer wall.

2. (canceled)
